(19) United States
(12) Patent Application Publication
(10) Pub. No.: US 2015/0001630 A1
(43) Pub. Date: Jan. 1, 2015

(54) STRUCTURE AND METHODS OF FABRICATING Y-SHAPED DMOS FINFET

(71) Applicant: GLOBALFOUNDRIES, Inc., Grand Cayman (KY)

(72) Inventor: Jagar Singh, Clifton Park, NY (US)

(21) Appl. No.: 13/929,165

(22) Filed: Jun. 27, 2013

(51) Int. Cl. H01L 29/78; H01L 29/66; H01L 27/092

(52) U.S. Cl. CPC H01L 29/7856; H01L 27/0924; H01L 29/66795; H01L 29/7816; H01L 29/66681
USPC 257/369; 257/409; 438/283

(57) ABSTRACT

A semiconductor FinFET device in fabrication includes a semiconductor substrate and at least one semiconductor fin coupled to the substrate. Each of the semiconductor fins further include a single drain branch coupled to at least two source branches at a common area, with the two source branches acting together as a source. A channel area is situated in the common area. In one example, the single drain branch and two source branches are coupled at the common area to form a generally Y-shaped fin. Further fabrication to complete the FinFET may then proceed.

### BACKGROUND OF THE INVENTION

1. Technical Field

The present invention generally relates to semiconductor devices and methods of fabricating semiconductor devices. More particularly, the present invention relates to the fabrication of Y-shaped diffused metal oxide semiconductor.

2 Background Information

Semiconductor devices or integrated circuits (IC) may include various voltage level devices, such as, for example, low, intermediate and high power devices. The low power devices may be used for complementary metal oxide semiconductor (CMOS) logic circuitry, while the intermediate voltage devices may be used for analog circuitry, and high power devices may be used for output high voltage (HV) interface stages. A commonly used high-voltage component for the high power devices is the lateral diffused metal oxide semiconductor (LDMOS) transistor, because of the several advantages associated with it such as, for example, fast switching speed, high input impedance and low power consumption.

The LDMOS transistors possess comparatively high breakdown voltage (BV), allowing them to support other electrical devices that operate at high voltages. Breakdown voltage (BV) is the voltage level at which an uncontrollable increase in current through the LDMOS transistor occurs. As the semiconductor device fabrication transitions to 20 nanometers and below, smaller LDMOS transistors with reduced turn-on-resistance (Ron) and enhanced circuit performance are developed. However, the reduced turn-on-resistance (Ron) leads to a reduction of breakdown voltage, which in turn degrades the performance of LDMOS transistors in high-voltage applications. Accordingly, there exists a trade-off between the breakdown voltage (BV) and the on-resistance (Ron) of the LDMOS transistors.

Hence, there continues to be a need for scalable semiconductor device transistors with enhanced performance.

### SUMMARY OF THE INVENTION

The shortcomings of the prior art are overcome and additional advantages are provided through the provision, in one aspect, of a FinFET, including a semiconductor substrate, at least one semiconductor fin coupled to the substrate, the at least one fin including a single drain branch, at least two source branches coupled to the drain branch at a common area, and a channel in the common area situated between and electronically coupling the at least two source branches and the drain branch.

In accordance with another aspect, a CMOS device is provided, including a semiconductor substrate, and at least one semiconductor fin coupled to the substrate. The at least one fin has a Y-shape and includes a single drain branch, at least two source branches coupled to the drain branch at a common area, a channel in the common area situated between and electronically coupling the at least two source branches and the drain branch, and a gate including metal, the gate being above and encompassing the common area.

In accordance with yet another aspect, a method of fabricating a FinFET is provided. The method includes providing a semiconductor substrate, creating at least one semiconductor fin coupled to the substrate, the at least one fin having a single drain branch and a plurality of source branches, the drain and source branches meeting at a common region of the at least one fin. The method further includes forming a gate over the common region of the at least one fin, the gate conforming to the at least one fin at the common region.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a top view of one example of a FinFET device, at an early stage of semiconductor fabrication, with a generally Y-shaped fin having two source branches coupled to one drain branch at a common area, in accordance with one or more aspects of the present invention.

FIG. 2 is a top view of another example of a generally Y-shaped fin having two linear source branches connected in parallel to a linear drain branch and a common linear channel region, in accordance with one or more aspects of the present invention.

FIG. 3 is a top view of still another example of a generally Y-shaped fin having two source branch regions, each source branch having two linear sections connected at an angle, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

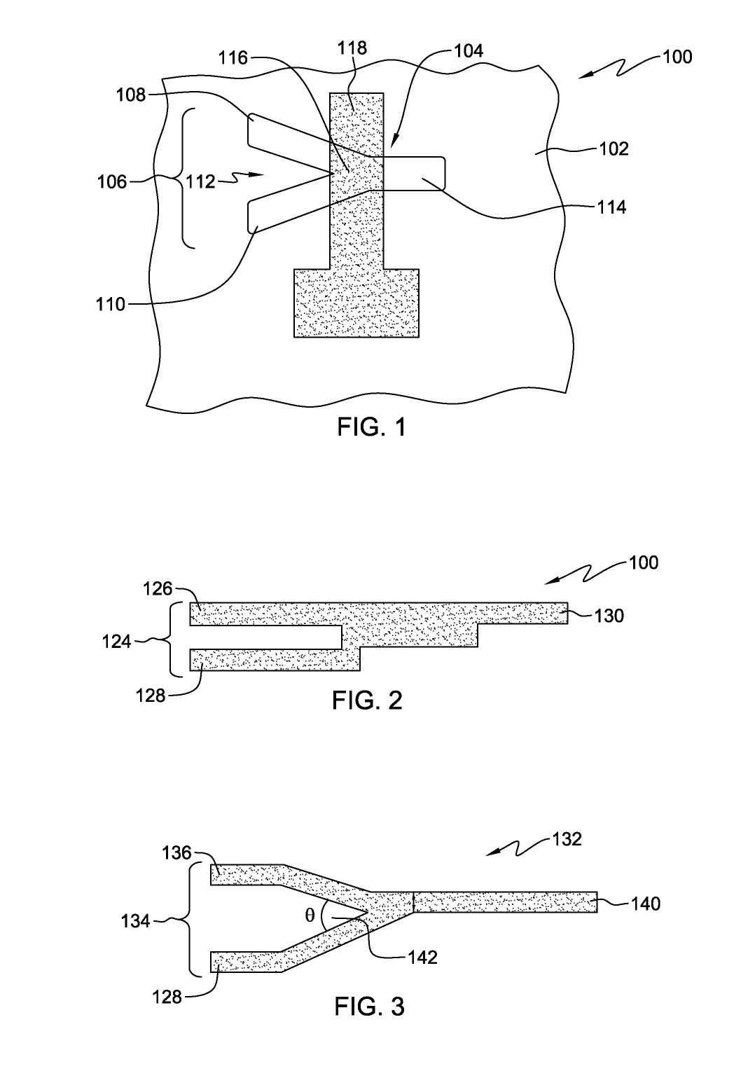

FIG. 1 schematically illustrates a top view of one example of a simplified FinFET device 100, in accordance with one or more aspects of the present invention, at an early stage of semiconductor fabrication, including a substrate 102 along with a fin structure 104 coupled to the semiconductor substrate. As one skilled in the art will know, a Field Effect Transistor (FET) has a source and a drain corresponding with a channel region situated between the source and the drain regions. In a FinFET, the source/drain/channel region are typically situated above the substrate in one or more raised structures roughly resembling fins in some designs. A FinFET is typically on the order of tens of nanometers in width and with single or multiple fins. Advantageously, the fin structure helps to control current leakage through the transistor in the off stage, and a double gate or tri-gate structure may be employed to control short channel effects.

Returning to the top view of the FinFET device 100 in FIG. 1, the semiconductor substrate may include, for example, bulk semiconductor material such as, for example, silicon, in the form of a bulk silicon wafer. In one example, substrate 102 may include any silicon-containing substrate including, but not limited to, silicon (Si), single crystal silicon, polycrystalline Si, amorphous Si, silicon-on-nothing (SON), silicon-on-insulator (SOI), or silicon-on-replacement insulator (SRI) substrates and the like. Substrate 102 may in addition or instead include various isolations, dopings and/or device features. The substrate may include other suitable elementary semiconductors, such as, for example, germanium (Ge) in crystal, a compound semiconductor such as silicon carbide (SiC), gallium arsenide (GaAs), gallium phosphide (GaP), indium phosphide (InP), indium arsenide (InAs), and/or indium antimonide (InSb) or combinations thereof. Further examples include an alloy semiconductor, for example, GaAsP, AlInAs, GaInAs, GaInP, or GaInAsP or combinations thereof.

Continuing with FIG. 1, the fin structure may include one or more fins 104, made of any suitable material. Each fin 104 includes at least two source branches 106 such as, for example, source branches 108 and 110, separated by spaces (e.g., space 112) on substrate 102. Each of the at least two source branches 106 are coupled to the drain branch 114 at a common area 116, resulting in a generally Y-shaped fin. Note that each of the at least two source branches 106 may be disposed at an angle of about 5 degrees to about 140 degree and may be electrically coupling the at least two source branches and the drain branch. The channel area (not specifically shown) is disposed between the at least two source branches 106 and drain branch 114 within or under the common area 116. It will be understood that the positioning of the at least two source branches and drain branch could be switched. The fabrication process may be continued further, for example, with a conventional “gate-last” process or a conventional “gate-first” process as applicable. In a conventional “gate-last” process, for instance, a sacrificial gate 118 is disposed, after subsequent conventional processes, over and encompassing the common area 116. The gate may include, in one example, polysilicon or polycrystalline silicon which, as known, may be employed to hold the gate positions for the subsequent metal gate material to be formed. In another example, in a conventional “gate-first” process, the gate 118 may include one or more conformally-deposited layers, such as, for example, gate dielectric layer, one or more work function layer and metal gate material. Note that these layers may be formed using a variety of different materials and techniques, such as, for example, atomic layer deposition (ALD) and chemical vapor deposition (CVD). The thickness of the layers may also vary, depending upon the particular application.

As integration density of transistors continues to increase, the cross-sectional area available for a gate electrode, as well as for contact structures to the active regions of the transistors, continues to decrease. This decrease in available footprint area for gate electrodes and contact structures may result in challenges to the performance characteristics of the transistors. Note that, however, the roughly Y-shaped fin with at least two source branches coupled to drain branch offers advantages associated with smaller footprint area for gate electrodes and contact structures without compromising the performance characteristics of the transistors.

As is understood in the art, the specific turn-on-resistance (R_{on,sp}) from drain region to the source region, in a typical diffused metal oxide semiconductor (DMOS) device is the sum of resistances of the source region (Rₛ), the channel (R_{ch}), the drift (R_{drift}) and the drain (R_{drain}). In general, the specific turn-on-resistance (R_{on,sp}) is measured by the equation,

R_{on,sp}=Rₛ+R_{ch}+R_{drift}+R_{drain}

The generally Y-shaped fin of the transistor, in the present invention, advantageously facilitates a decrease in the total resistance of the source (Rₛ) with an increase in the number of source regions. Note that the resistances in the channel region (R_{ch}) and drift region (R_{drift}) are also decreased, while keeping the resistance in the drain region (R_{d}) unchanged. This decrease in the resistance of the drain region (R_{d}) exhibits higher breakdown voltage (BV) while maintaining lower leakage current, which in turn, improves the performance of the semiconductor device. In addition, as the integration density of the transistor may be increased with the increasing number of source regions, the electric field center point may be modulated by choosing a location on the at least one fin, so as to improve the semiconductor device performance.

As is understood in the art, the reduced surface field (RESURF) design technique seeks to reduce peak electric fields to improve breakdown voltage, and provides better trade-off between breakdown voltage (BV) and specific turn-on-resistance (R_{on,sp}) as compared to the conventional semiconductor devices. Note that the RESURF design technique is affected by a variety of factors such as, for example, doping of the lateral depletion layer, and the breakdown voltage (BV) of conventional semiconductor devices is limited by factors such as, for example, buried oxide thickness, fin thickness and the drift layer length. The roughly Y-shaped fin of the present inventive transistor spreads (increases) the source side area, which reduces the peak electric fields, and further advantageously facilitates improved breakdown voltage by modulating the optimum parameters, for instance, relative thickness, width and height of the resultant roughly Y-shaped fin. In one example, the height of the resultant Y-shaped fin may be about 5 nanometers to about 10000 nanometers and width of the resultant Y-shaped fin may be about 10 nanometers to about 20 nanometers. In another example, the length of the source branches may be about 50 nanometers to about 10000 nanometers, while the length of the drain branch may be about 50 nanometers to about 10000 nanometers. The breakdown voltage of the roughly Y-shaped fin may further be improved by reducing the fin doping of the lateral depletion layer and further modulating the electric field center point.

FIGS. 2 and 3 depict the top views of examples of generally Y-shaped fin transistors that can be fabricated with currently known techniques. In particular, FIG. 2 shows a generally Y-shaped fin with at least two source branches 120 having a plurality of linear fin regions 124 such as, for example, linear fin regions 126 and 128. Note that the linear fin regions 124 are connected in parallel and are coupled to a drain branch 130 at a common area to form a roughly Y-shaped fin.

Alternatively, FIG. 3 shows a roughly Y-shaped fin with at least two source branches 132 having a plurality of linear fin regions 134, such as linear fin regions 136 and 138, with each of the linear fin regions 134 joined at an outer angle θ 142 of about 45°.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A FinFET, comprising:
a semiconductor substrate;
at least one semiconductor fin coupled to the substrate, the at least one fin comprising:
a single drain branch;
at least two source branches coupled to the drain branch at a common area; and
a channel in the common area situated between and electronically coupling the at least two source branches and the drain branch.

2. The FinFET of claim 1, wherein the at least two source branches together act as a source, and wherein the at least one fin has a generally Y-shape.

3. The FinFET of claim 2, wherein each of the at least two source branches comprises a plurality of linear fin regions.

4. The FinFET of claim 3, wherein the plurality of linear fin regions comprises two linear fin regions joined at an outer angle of about 45°.

5. The FinFET of claim 2, wherein the at least one fin comprises a plurality of linear fin regions connected in parallel.

6. The FinFET of claim 2, wherein the at least one fin has a height of about 5 nm to about 10000 nm.

7. The FinFET of claim 2, wherein the single drain branch has a length of about 50 nm to about 10000 nm.

8. The FinFET of claim 2, wherein the at least two source branches each have a length of about 50 nm to about 10000 nm.

9. The FinFET of claim 2, wherein the at least two source branches comprise two source branches, and wherein an angle between the two source branches is a about 5 degrees to about 140 degrees.

10. The FinFET of claim 1, wherein the FinFET further comprises a gate above and encompassing the channel.

11. A CMOS device, comprising:
a semiconductor substrate;
at least one semiconductor fin coupled to the substrate, the at least one fin having a Y-shape and comprising:
a single drain branch;
at least two source branches coupled to the drain branch at a common area;
a channel in the common area situated between and electronically coupling the at least two source branches and the drain branch; and
a gate comprising metal, the gate above and encompassing the common area.

12. A method, comprising:
providing a semiconductor structure, the structure comprising:
a semiconductor substrate; and
at least one semiconductor fin coupled to the substrate, the at least one fin comprising:
a single drain branch;
at least two source branches coupled to the drain branch at a common area and
a channel in the common area situated between and electronically coupling the at least two source branches and the drain branch; and
forming a gate over the common region of the at least one fin, the gate conforming to the at least one fin at the common region.

13. The method of claim 12, wherein the gate comprises a dummy gate, the method further comprising replacing the dummy gate with a metal gate.

14. The method of claim 12, wherein the creating comprises choosing a location on the at least one fin for an electric field center point.

15. The method of claim 14, wherein choosing a location comprises choosing a length for the drain branch and a length for the source branches.

16. The method of claim 14, wherein the plurality of source branches comprises two source branches, and wherein choosing a location comprises choosing an angle between the two source branches.

17. The method of claim 12, wherein the creating comprises choosing a height for the at least one fin to achieve a desired level of current through the FinFET.

18. The method of claim 14, wherein choosing a location comprises choosing a width for the drain branch and a length for the source branches.
